(19) United States
(12) Patent Application Publication
(10) Pub. No.: US 2011/0062424 A1
(43) Pub. Date: Mar. 17, 2011

(54) POLYMER COMPOSITIONS COMPRISING ADDITIVE BLOCK COPOLYMERS

(75) Inventors: Stephen James Grunzinger, Oceanside, CA (US); Amane Mochizuki, San Diego, CA (US)

(73) Assignee: NITTO DENKO CORPORATION, Osaka (JP)

(21) Appl. No.: 12/877,311

(22) Filed: Sep. 8, 2010

Related U.S. Application Data
(60) Provisional application No. 61/241,449, filed on Sep. 11, 2009.

(51) Int. Cl. H01L 51/50; C08L 83/10; C08L 53/00

(52) U.S. Cl. 257/40; 525/474; 525/477; 525/92 G; 525/476; 257/E51.018

(57) ABSTRACT

Disclosed herein are some embodiments related to a polymer composition comprising a base polymer and a block copolymer additive. Laminated constructs, methods of preparing the polymer compositions and the laminate constructs, and devices related thereto are also disclosed.

### CROSS-REFERENCES TO RELATED APPLICATIONS

This application claims the benefit of U.S. Provisional Application No. 61/241,449, filed Sep. 11, 2009, which is incorporated by reference herein in its entirety.

### BACKGROUND OF THE INVENTION

1. Field of the Invention

This invention relates to polymers, such as laminate constructs of polymers.

2. Description of the Related Art

Light-emitting semiconductor devices such as light-emitting diodes (LED) may be subjected to many environmental distresses during the manufacture of the devices and during the subsequent use. Exemplary environmental stresses include expansion and contraction of the material, physical shock, thermal shock, long-term thermal exposure and moisture. Thermal shock, or the exposure to peak high temperatures, may occur during the manufacturing process, e.g., passing exposure to soldering temperatures. Operating temperatures immediately adjacent to the LED may achieve temperatures in excess of 150° C. Long term thermal exposure may occur when the heat or radiant energy is generated by the LED. Moisture may be a problem when the LED is exposed to ambient atmospheric conditions. Any of these aspects may adversely affect the operation or lifetime of the device.

In order to reduce these adverse effects, some working in the area have encapsulated the LED in an epoxy resin. Encapsulation may be intended to impart a physical toughness to the LED and environmentally isolate the LED from adverse conditions. The conventional transparent epoxy resin composition, however, may have poor moisture resistance due to high water absorption. Conventional transparent epoxy resin compositions may also have poor light resistance (e.g. a tendency to degrade or deteriorate in the presence of light) due to low transmittance for short wavelength light. Furthermore, conventional epoxy resins may be colored due to light deterioration. In addition, when an epoxy resin composition is used as an encapsulating resin, internal stress may be generated by shrinkage from curing the epoxy resin composition or by distortion due to a difference in coefficient of linear expansion between the epoxy resin and the optical semiconductor element. As a result, the optical semiconductor element may be deteriorated. This may be a problem, for example, if the optical semiconductor element is an emissive element because it may reduce the brightness of the device. Furthermore, because of the aromatic character of bisphenol-A based epoxy resins, these encapsulants are typically less stable to ultraviolet radiation. Therefore, these materials may tend to degrade on extended exposure to ultraviolet light. Furthermore, epoxy based resins tend to become more brittle with time and exposure to thermal energy generated by the LED.

Alternatively, silicon based resins have been utilized as an encapsulating material in attempts to reduce adverse environmental effects upon the LED. Silicone based gels are less affected by LED generated temperatures and thus can provide increased service lifetime and continued radiant luminosity. However, these resins may have an increased level of surface tackiness, entrapping air-borne materials and reducing the transparency of the resin. These silicon gels may also be susceptible to physical deformation due to impact. Harder silicon resins, e.g., those substituted with phenol groups, may be less tacky and better able to resist physical deformation, but may suffer from the same degeneration to which epoxy based resins may be susceptible. These harder silicon resins also may have decreased adhesion to the LED, LED supporting substrate or LED packaging. As a result, delamination or peeling of the resin from these components may occur, which may reduce the protectiveness of the harder resins.

Additional attempts to address these problems have included providing a composite silicon/epoxy material as an encapsulating material. However, these composite encapsulating layers may also suffer from temperature related degradation and corresponding decreased transparency and reduced device effectiveness. Still further attempts to resolve these problems have included the creation of plural distinct layers composed of a silicone gel immediately adjacent to the LED and a protective layer of epoxy resin covering the silicone gel layer. Since the epoxy layer is distanced from the LED, the local environmental temperatures are lower, reducing the thermal degradation of the protective epoxy layer. However, delamination between the epoxy resin and silicon gel layers may create air voids at the respective layer interfaces, and may decrease transparency and thus device efficacy.

Surface modifying macromolecules have been used to increase the adherence of resin layers. For example, fluorinated small or macromolecules which migrate to the surface of the first resin layer during curing and provide functional groups or additional adhesive properties to the cured surface have been used. However, in addition to being surface active, fluorine containing species are also well known to reduce adhesion. Thus there is a need for an environmentally protective layer of material to isolate the LED from environmental conditions while minimizing degradation or reduction in transparency of the layers due to environmental conditions.

### SUMMARY OF THE INVENTION

Some embodiments provide a polymer composition comprising: a base polymer; and a block copolymer additive comprising at least one polysiloxane block and at least one functional block, wherein the functional block comprises at least one branched repeat unit and at least one polarizable organic functionality comprising at least one of: oxygen, nitrogen, sulfur, and a carbon-carbon multiple bond; wherein the polymer composition has at least one surface, and the surface of the polymer composition has a greater concentration of the block copolymer additive than polymer composition which is not present at the surface; and wherein the weight ratio of base polymer to block copolymer additive is at least about 9 to 1.

Some embodiments provide a laminated construct comprising: a first solid polymer comprising silicone and an additive comprising a block copolymer, wherein the block copolymer comprises at least one polysiloxane block and at least one functional block, wherein the functional block comprises at least one branched repeat unit; and a second solid polymer attached to the first solid polymer at an interface, wherein the attachment between the first solid polymer and the second solid polymer comprises covalent bonding between the functional block of the additive and the second solid polymer at the interface.

Some embodiments provide method of preparing a laminate of at least two different solid polymers, comprising: providing a first polymer comprising silicone; mixing a block copolymer additive with the first polymer to form a mixed polymer, wherein the block copolymer additive comprises at least one polysiloxane block and at least one functional block; concentrating the functional block at a surface of the mixed polymer; reacting the functional block concentrated at the surface of the mixed polymer with a surface of a second polymer to form an amount of covalent bonds effective to provide enhanced adhesion between the surfaces of the mixed polymer and the second polymer; wherein, if either the mixed polymer or the second polymer is not a solid, each polymer is capable of solidifying after the functional block has concentrated at the surface.

Some embodiments provide a light-emitting device comprising: a substrate; a light-emitting diode; and a laminated construct described herein; wherein the light-emitting diode is disposed between the substrate and the laminated construct.

These and other embodiments are described in greater detail below.

### BRIEF DESCRIPTION OF THE DRAWINGS

FIG. 1 depicts one embodiment of a light-emitting device comprising an embodiment of a laminate construct provided herein.

FIG. 2 depicts a method which may be used to measure adhesion of some embodiments.

FIG. 3 depicts adhesion plotted against concentration of some embodiments.

FIGS. 4A-C depict scanning electron microscope images of some embodiments.

FIG. 5 is an attenuated total reflectance infrared spectrum of some embodiments.

### DETAILED DESCRIPTION OF THE PREFERRED EMBODIMENT

As used herein, the term “silicone” has the ordinary meaning understood by one of ordinary skill in the art. In some embodiments, the term “silicone” refers to a polymeric material comprising silicon, carbon, hydrogen, and oxygen. A polysiloxane is an example of a silicone.

As used herein, the term “polysiloxane” has the ordinary meaning understood by one of ordinary skill in the art. In some embodiments, the term “polysiloxane” refers to a polymer comprising siloxane repeat units. The term “siloxane” has the ordinary meaning understood by one of ordinary skill in the art. In some embodiments, the term “siloxane” refers to a unit comprising —Si—O— where the silicon atom may bear two groups selected from: hydrogen and a hydrocarbon group. Poly(dimethylsiloxane) is an example of a polysiloxane.

As used herein, the term “block copolymer” has the ordinary meaning understood by one of ordinary skill in the art. See, e.g., R. J. Young, “Introduction to Polymers,” Chapman and Hall, New York, 1981 (pp. 64-66). In some embodiments, the term “block copolymer” refers to a copolymer comprising at least two distinct homopolymer blocks joined to one another, e,g., joined end-to-end by covalent bonding. The term “polymer block” has the ordinary meaning understood by one of ordinary skill in the art. In some embodiments, the term “polymer block” refers to a portion of homopolymer that constitutes a block within a block copolymer. As used herein, the term “triblock copolymer” has the ordinary meaning understood by one of ordinary skill in the art. In some embodiments, the term “triblock copolymer” refers to a polymer having three distinct polymer blocks.

As used herein, the term “polysiloxane block” refers to a polymer block comprising siloxane repeat units.

As used herein, the term “repeat unit” has the ordinary meaning understood by one of ordinary skill in the art. In some embodiments, the term “repeat unit” refers to a part of a polymer which attaches in at least two positions to another repeat unit or a terminal unit of the polymer.

As used herein, the term “branched repeat unit” has the ordinary meaning understood by one of ordinary skill in the art. In some embodiments, the term “branched repeat unit” refers to a repeat unit which attaches in at least three positions to another repeat unit or a terminal unit of the polymer.

As used herein, the term “terminal unit” has the ordinary meaning understood by one of ordinary skill in the art. In some embodiments, the term “terminal unit” refers to a part of a polymer which attaches at only one position to a repeat unit of the polymer.

As used herein, the term “polarizable organic functionality” has the ordinary meaning understood by one of ordinary skill in the art. In some embodiments, the term “polarizable organic functionality” refers to a moiety comprising a carbon-carbon multiple bond, or a bond between a carbon atom and a heteroatom. Some non-limiting examples of polarizable organic functionality include: aldehyde, amine, ammonium, amide, imine, ketimine, imide, azide, azo, carbonate, ketone, carboxamide, carboxyl, carboxylate, epoxide, nitrile, cyanate, isocyanide, isocyanate, isothiocyanate, thioether, disulfide, ester, ether, haloformyl, hydroperoxy, nitro, peroxy, sulfonyl, hydroxyl, sulfhydryl, sulfinyl, thiol, thioether, thioester, sulfonyl, thiocyanate, vinyl, ethynyl, etc.

As used herein, the term “epoxy resin” has the ordinary meaning understood by one of ordinary skill in the art. In some embodiments, the term “epoxy resin” refers to a product of a reaction between a epichlorohydrin or a related haloalkylene oxide and bisphenol-A or a related diphenolic compound such as a dialkyldi(hydroxyphenyl)methane or a dihydroxyphenyl oxide.

As used herein, the term “polyurethane” has the ordinary meaning understood by one of ordinary skill in the art. In some embodiments, the term “polyurethane” refers to a series of hydrocarbon chains, such as a series of —(CH₂)ₙ— chains, where n is about 1-20, which are connected by carbamate groups. In some embodiments, the term “polyurethane” refers to a reaction product of at least one polyisocyanate and at least one polyol.

As used herein, the term “polyimide” has the ordinary meaning understood by one of ordinary skill in the art. In some embodiments, the term “polyimide” refers to a polymer comprising at least one imide-containing repeat unit.

As used herein, the term “aryl” has the ordinary meaning understood by one of ordinary skill in the art. In some embodiments, the term “aryl” refers to an aromatic moiety, including, but not limited to, a carbocyclic aromatic moiety such as phenyl, naphthyl, etc.; and a heteroaryl moiety such as thienyl, furyl, pyridinyl, etc.

Unless otherwise indicated, when a structural feature such as aryl is referred to as being “optionally substituted,” it is meant that the feature may have no substituents or may have one or more substituents. A structural feature that is “substituted” has one or more substituents. The term “substituent” has the ordinary meaning known to one of ordinary skill in the art. In some embodiments, the substituent is an ordinary organic moiety known in the art, which may have a molecular weight (e.g. the sum of the atomic masses of the atoms of the substituent) of less than about 500 g/m, about 300 g/m, about 200 g/m, about 100 g/m, or about 50 g/m. In some embodiments, the substituent comprises: about 0-30, about 0-20, about 0-10, or about 0-5 carbon atoms; and about 0-30, about 0-20, about 0-10, or about 0-5 heteroatoms independently selected from: N, O, S, P, Si, F, Cl, Br, I, and combinations thereof; provided that the substituent comprises at least one atom selected from: C, N, O, S, P, Si, F, Cl, Br, and I. Examples of substituents include, but are not limited to, alkyl, alkenyl, alkynyl, carbazolyl, cycloalkyl, cycloalkenyl, cycloalkynyl, aryl, diarylamino, heteroaryl, heteroalicyclyl, aralkyl, heteroaralkyl, (heteroalicyclyl)alkyl, hydroxy, protected hydroxy, alkoxy, aryloxy, acyl, ester, mercapto, alkylthio, arylthio, cyano, halogen, carbonyl, thiocarbonyl, O-carbamyl, N-carbamyl, O-thiocarbamyl, N-thiocarbamyl, C-amido, N-amido, S-sulfonamido, N-sulfonamido, C-carboxy, protected C-carboxy, O-carboxy, isocyanato, thiocyanato, isothiocyanato, nitro, silyl, sulfenyl, sulfinyl, sulfonyl, haloalkyl, haloalkoxyl, trihalomethanesulfonyl, trihalomethanesulfonamido, and amino, including mono- and di-substituted amino groups, and the protected derivatives thereof.

As used herein, the term “alkyl” refers to a monovalent moiety derived from an alkane, such as —CH₂, —CH₂CH₃, etc., and the term “alkylene” refers to a divalent moiety derived from an alkane, such as —CH₂CH₂—, —CH(CH₃)—, etc.

Some embodiments provide a polymer composition comprising a base polymer and a block copolymer additive. The base polymer may be any polymer or mixture of polymers, including, but not limited to, polyalkylenes such as polyethylene, etc.; polystyrenes; polyacrylic acids or polyacrylic acid esters such as poly(methylacrylate), poly(methylmethacrylate), poly(methylacrylic acid), polyacrylic acid, etc.; polyurethanes; epoxides; polyesters; polyfluorocarbons such as polytetrafluoroethylene; polyalkylene oxides; silicon polymers; etc. In some embodiments, the base polymer comprises silicon, such as polysiloxane or silicone. In some embodiments, the base polymer comprises a silicone resin.

The block copolymer additive may be any block copolymer comprising at least one polysiloxane block and at least one functional block. In some embodiments, the block copolymer additive may be substantially free of fluorine.

In some embodiments, the block copolymer additive is a triblock copolymer of the general formula A-B-A′, wherein A and A′ are independently functional blocks, and B is a polysiloxane block. In these embodiments, A and A′ may be substantially similar, or they may be different. For example, in some embodiments, A and A′ may be prepared by reacting a difunctional —B— with a single reagent to provide A and A′ which may differ only in the number of repeat units, or other similar minor variation in structure. Alternatively, in other embodiments, A and A′ may be attached using two substantially different reagents.

The polysiloxane block may comprise any polysiloxane. In some embodiments, the polysilane block comprises a polydialkylsiloxane, such as a polydi(C₁₋₈alkyl)siloxane (e.g. wherein each alkyl group may have 1, 2, 3, 4, 5, 6, 7, or 8 carbon atoms, such as polydimethylsiloxane, polydiethylsiloxane, polyethylmethylsiloxane, etc.). In some embodiments, the polysiloxane block comprises polydimethylsiloxane. The number of siloxane repeat units may vary, in some embodiments, the polysiloxane comprises at least about 10, about 1000, or about 50,000 siloxane repeat units, up to about 120,000, about 200,000, or about 1,000,000 siloxane repeat units. In some embodiments, the length of the polysiloxane block can be varied by selecting a divinylterminated polymethylsiloxane with a different molecular weight, e.g., from about 6,000 g/m (e.g., about 77 repeat units) to about 49,500 g/m (about 635 repeat units) molecular weight.

The functional block may comprise at least one branched repeat unit and at least one polarizable organic functionality. The polarizable organic functionality may comprise at least one of: an oxygen atom, a nitrogen atom, a sulfur atom, and a carbon-carbon multiple bond. In some embodiments the polarizable organic functionality is selected from: aldehyde, amine, ammonium, amide, imine, ketimine, imide, azide, azo, carbonate, ketone, carboxamide, carboxyl, carboxylate, epoxide, nitrile, cyanate, isocyanide, isocyanate, isothiocyanate, thioether, disulfide, ester, ether, haloformyl, hydroperoxy, nitro, peroxy, sulfonyl, hydroxyl, sulfhydryl, sulfinyl, thiol, thioether, thioester, sulfonyl, thiocyanate, vinyl, ethynyl, etc. In some embodiments, the functional block may comprise an epoxide. In some embodiments, the functional block may comprise about 2 to about 10,000 repeat units, about 3 to about 100 repeat units, or about 3 to about 45 repeat units.

In some embodiments, the functional block may comprise Si. For example, in some embodiments, the functional block comprises: at least one terminal unit represented by Formula A:

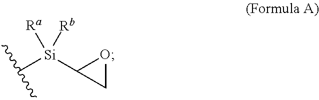

and
at least one repeat unit represented by Formula B:

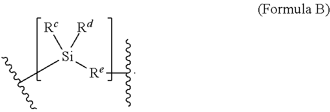

In some embodiments, R^{a} and R^{b} may independently be: C₁₋₆ alkyl, such as methyl, ethyl, propyl isomers (e.g. n-propyl, isopropyl, etc.), cyclopropyl, butyl isomers, cyclobutyl isomers (e.g. cyclobutyl, methylcyclopropyl, etc.), pentyl isomers, etc.; optionally substituted phenyl, such as phenyl having 0, 1, or 2 substituents independently selected from C₁₋₃ alkyl, F, Cl, Br, and OCH₃; or

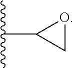

In some embodiments, R^{c} and R^{d} may independently be: C₁₋₆ alkyl, such as methyl, ethyl, propyl isomers (e.g. n-propyl, isopropyl, etc.), cyclopropyl, butyl isomers, cyclobutyl isomers (e.g. cyclobutyl, methylcyclopropyl, etc.), pentyl isomers, etc.; C₂₋₄ alkylene, such as —C₂H₄—, —C₃H₆—, —C₄H₈—, etc.; optionally substituted phenyl, such as phenyl having 0, 1, or 2 substituents independently selected from C₁₋₃ alkyl, F, Cl, Br, and OCH₃; or

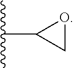

In some embodiments, R^{e} is C₂₋₄ alkylene, such as —C₂H₄—, —C₃H₆—, —C₄H₈—, etc. With respect to formula B, in some embodiments wherein any of R^{c} and/or R^{d} is alkylene, the R^{c} and/or R^{d} may attach to another repeat unit or a terminal unit.

In some embodiments, the functional block may comprise: at least one terminal unit represented by Formula 1:

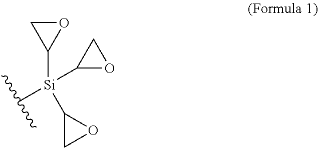

and at least one repeat unit represented by at least one of Formula 2, Formula 3, and Formula 4:

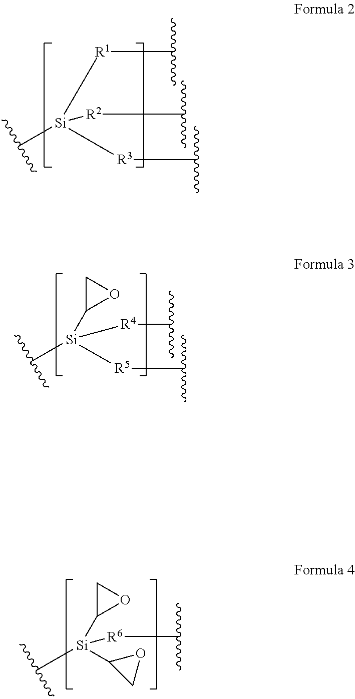

wherein each R¹, R², R³, R⁴, R⁵, and R⁶ may independently be —CH₂CH₂— or —CH(CH₃)—.

In some embodiments, the block copolymer additive may comprise at least one repeat unit represented by the Formula 5:

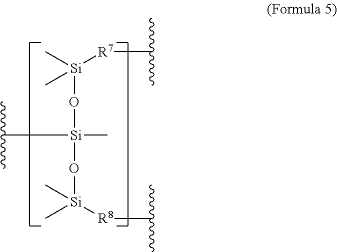

wherein R⁷ and R⁸ may independently be —CH₂CH₂— or —CH(CH₃)—.

In Formulas A, B, and 1-5,

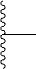

may indicate a point of attachment. In some embodiments, the attachment may be to repeat unit (of either a functional block or a polysiloxane block) or a terminal unit. In some embodiments, the attachment may be to a silicon or oxygen atom of a repeat unit of a polysiloxane block, a silicon atom of a repeat unit of a functional block, or a silicon atom of a terminal unit.

The mass of the polysiloxane block and the mass of the functional block may vary with respect to the mass of the block copolymer additive as a whole. In some embodiments, the polysiloxane block may comprise about 5% to about 99%, about 20% to about 95%, or alternatively, about 50% to about 70% of the mass of the block copolymer additive. In some embodiments, the functional block may comprise about 20% to about 95%, about 20% to about 80%, or alternatively, 30% to about 50% of the mass of the block copolymer additive.

In some embodiments, the block copolymer additive may be a triblock copolymer which may be an epoxidation product of a precursor triblock copolymer, wherein the precursor triblock copolymer may comprise a central polydimethylsiloxane block, and a poly(divinyldihydrosilane) block on each end of the polydimethylsiloxane block. In some embodiments, the polydimethylsiloxane block may be about 60% to about 70% of the mass of the triblock copolymer and the sum of the masses of the two poly(divinyldihydrosilane) blocks may be about 30% to 40% of the mass of the triblock copolymer.

The polymer composition may generally have at least one surface, and the surface of the polymer composition may have a greater concentration of the block copolymer additive than polymer composition which is not present at the surface. For example, in some embodiments, the number of block copolymer additive molecules on the surface in a given area may be greater than the number of block copolymer additive molecules that would be present in an equal area on a surface created by cutting through a portion of the polymer composition not at the surface. In some embodiments, the concentration of the block copolymer additive is graded as a function of depth. In some embodiments, the concentration of the block copolymer additive decreases as the depth increases.

The weight ratio of base polymer to block copolymer additive may be at least about 9 to 1. In some embodiments, the amount of the block copolymer additive may be in the range of about 0.0001% (w/w) to about 5% (w/w), about 0.001% (w/w) to about 1% (w/w), about 0.01% (w/w) to about 0.5% (w/w), or alternatively, about 0.01% (w/w) to about 0.1% (w/w) of the polymer composition.

The polymer composition may be prepared by any of many methods known in the art. In some embodiments, the polymer composition may be prepared by a process comprising mixing the block copolymer additive with the base polymer, and allowing the block copolymer additive to concentrate at the surface.

The polymer composition may further comprise a second solid polymer. The second polymer may be any type of polymer, including those described above with respect to the base polymer. In some embodiments, the second solid polymer may be an epoxy resin, a polyurethane, a polyimide, a polysiloxane, or a silicone.

In some embodiments, the second polymer may comprise covalent bonds to atoms of the functional block of the additive. In some embodiments, at least a portion of the covalent bonds to atoms of the functional block may comprise —O—, wherein the oxygen atom has one covalent bond to a carbon atom of the functional block and one covalent bond to a carbon atom of the second solid polymer.

In some embodiments, the amount of covalent bonds to atoms of the functional block may be effective to enhance adhesion to the surface of the base polymer. The enhancement of adhesion may be determined, for example, by measuring the adhesion between a first pair of polymers and a second pair of polymers, wherein the first pair of polymers comprises covalent bonds between the second polymer and the functional block of the additive, and the second pair of polymers is identical to the first pair of polymers, except that the second pair of polymers has no additive, and thus no covalent bonds between the second polymer and the functional block.

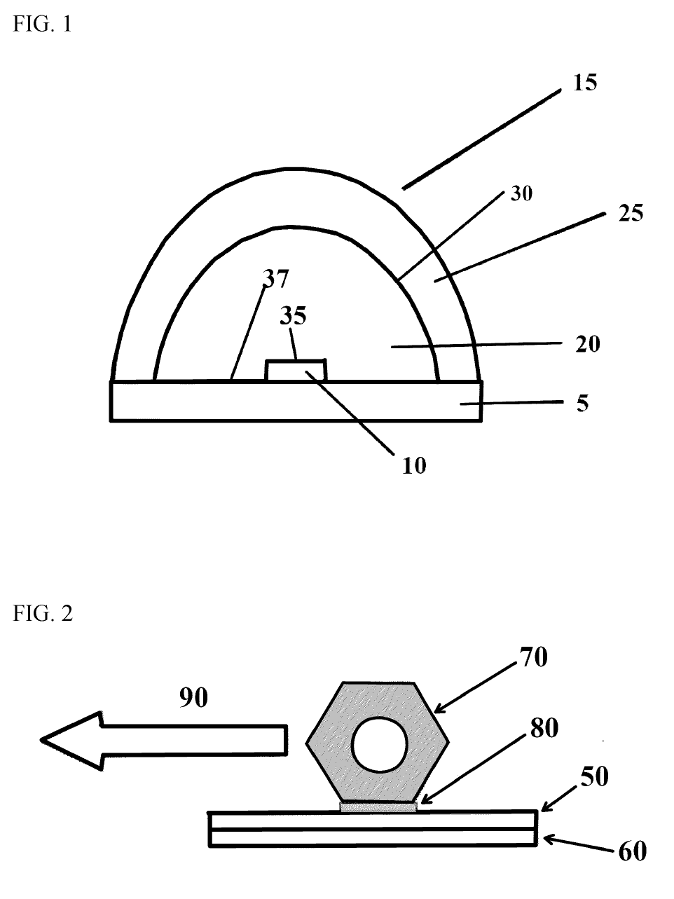

Some embodiments provide a light-emitting device comprising a substrate, a light emitting diode, and a laminate substrate described herein. One embodiment of such a device is shown in FIG. 1. In this particular embodiment, a substrate 5 is provided upon which a light-emitting diode 10 is mounted. The light-emitting diode 10 is disposed between the substrate 5 and a laminated construct 15. The laminated construct comprises a first solid polymer 20 (such as a silicone resin in some embodiments), which fills the space between the light-emitting diode 10 and the substrate 5 and the second solid polymer 25 (such as an epoxy resin in some embodiments). The first polymer 20 and the second polymer 25 are in contact with one another at a first interface 30 which comprises covalent bonds between the two polymers. In some embodiments, the first polymer 20 and the light-emitting diode 10 may be in contact with one another at a second interface 35 which comprises covalent bonds between an interfacial portion of the first polymer 20 and an interfacial portion of the light-emitting diode 10. In some embodiments, the first polymer 20 and the substrate 5 may be in contact with one another at a third interface 37 which comprises covalent bonds between an interfacial portion of the first polymer 20 and an interfacial portion of the substrate 5. Additional interfaces of a similar character may be present between the first polymer 20 and other parts of the device.

With regard to the laminate constructs, some embodiments comprise: a first solid polymer comprising silicone and an additive comprising a block copolymer, and a second solid polymer. In these embodiments, the block copolymer may comprise at least one polysiloxane block, such as any polysiloxane block described above, and at least one functional block, such as any functional block described above. In some embodiment, the functional block may comprise at least one branched repeat unit, such as any branched repeat unit described above. The second solid polymer may be any polymer, such as any second polymer described above. In these embodiments, the two solid polymers remain in contact with one another via covalent bonding between the functional block of the additive and the second solid polymer at an interface between the two solid polymers.

In some embodiments, a laminate of at least two different solid polymers may be prepared by the following method. A first polymer comprising silicone having at least one surface may be provided, and a block copolymer additive may be mixed into the first polymer to form a mixed polymer. The block copolymer additive may comprise at least one polysiloxane block, such as any polysiloxane block described above, and at least one functional block, such as any functional block described above. The functional block may be allowed to concentrate at the surface of the mixed polymer. For example, if the two are mixed in a liquid form, the functional block may preferentially migrate to the surface of the polymer. The functional block may then be reacted with a surface of a second polymer to form an amount of covalent bonds effective to provide enhanced adhesion between the surface of the mixed polymer and the surface of the second polymer. In some embodiments, if either the mixed polymer or the second polymer is not a solid, each polymer is capable of solidifying after the functional block has concentrated at the surface.

Although there are many methods that may be used to provide the devices described herein, an LED such as the embodiment depicted in FIG. 1, may be prepared by the following method. An LED may be provided which is encapsulated in a first polymer comprising: a) silicone and b) an additive comprising a block copolymer. The polymer may be prepared by any method described herein or by another method consistent with this disclosure. This polymer may be allowed to cure, and a second polymer may be coated on the first polymer which gives the desired device upon curing. In another embodiment, an uncured combination of the first polymer and the additive can be added to a cured second polymer or other hard surface which give the desired device upon curing

### Example 1

Divinylterminated polydimethylsiloxane (about 0.72 g, Mol. Wt. 49,500, Gelest, Morrisville, Pa., USA), divinylhydrosilane (about 0.37 g), toluene (about 2.5 mL), and platinum (Pt-octanol, about 0.25 mg) were stirred at about 60° C. for about 17.5 h. The toluene was then removed in vacuo to provide a triblock copolymer.

The triblock copolymer (about 1.09 g, 34% hyperbranched) prepared as described above, toluene (about 11 mL), and 3-chloroperbenzoic acid (about 1.61 g) were stirred at about room temperature for about 24 hours. The toluene was then removed in vacuo, and the residue was dissolved in ethyl acetate. K₂CO₃ was added (about 1.30 g), and the mixture was stirred about room temperature for about 18 hours. The solids were then centrifuged off, and the ethyl acetate was removed in vacuo to provide the epoxidized triblock product.

### Example 1a

Another embodiment of the polymer composition was prepared as in Example 1, except that 6,000 Mol. Wt. Divinylterminated polydimethylsiloxane (0.72 g) was used instead of 49,000 Mol. Wt. Divinylterminated polydimethylsiloxane.

### Example 2

Use of the epoxidized triblock copolymer, prepared as described above, as an embodiment of a block copolymer additive was tested as shown in FIG. 2. The epoxidized triblock copolymer was blended with a silicone resin to provide 0.001% (w/w), 0.01% (w/w), 0.1% (w/w), or 1% (w/w) of the triblock copolymer additive. The blended silicone resin 50 with triblock copolymer additive was then applied to a glass substrate 60 and allowed to cure. After the silicone resin 50 had cured, a metal stub 70 was affixed to the silicone resin 50 using an epoxy resin 80. A force 90 was then applied parallel to the surface and the force required to remove the metal stub was recorded. The results were compared to a similar experiment performed without adding any epoxidized triblock copolymer additive to the silicone resin.

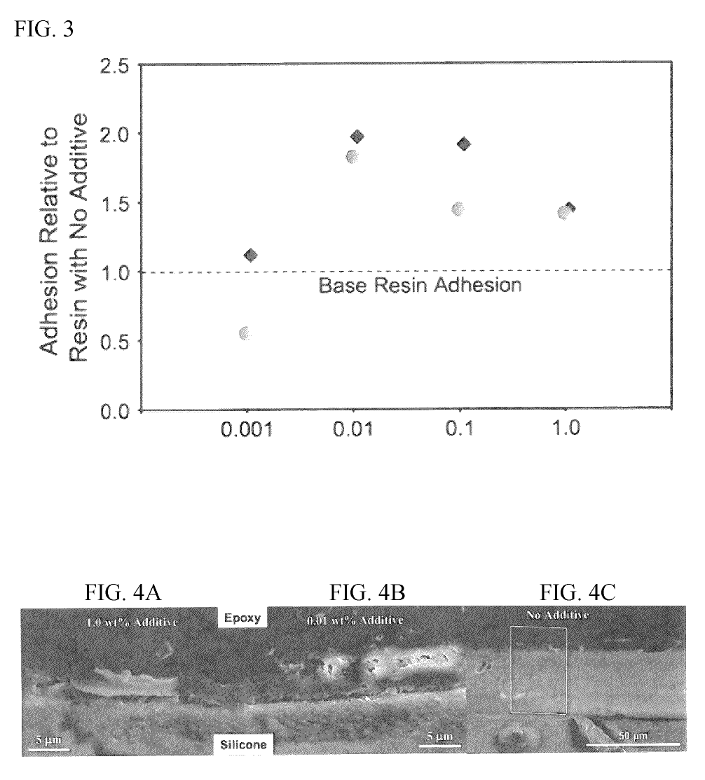

FIG. 3 depicts the adhesion plotted against concentration of the epoxidized triblock copolymer additive. The squares represent data generated using the polymer composition described in Example 1. The lighter circles represent data generated using the polymer composition described in Example 1a. The plots are normalized to the force required to remove the stub without the additive. Values greater than 1 indicate improved adhesion.

FIG. 4 depicts scanning electron microscope images of a silicone film cured with 1% (w/w) additive (FIG. 4A) and 0.01% (w/w) additive (FIG. 4B), and without additive (FIG. 4C). FIG. 4C shows that the layers separated for the sample prepared without additive.

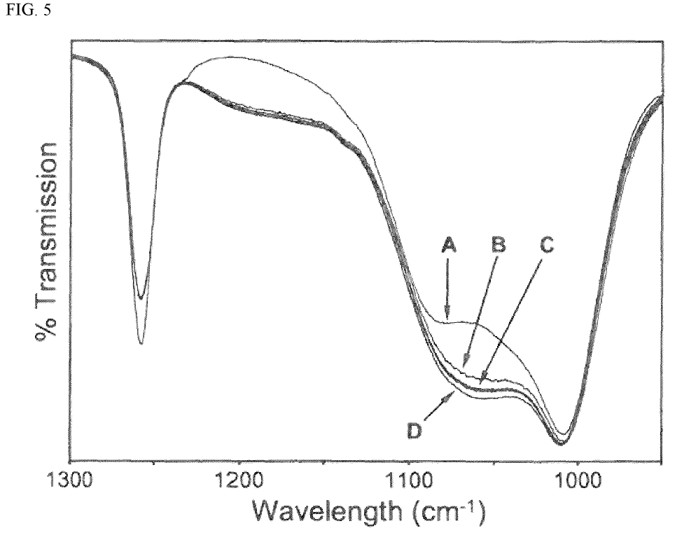

FIG. 5 is an attenuated total reflectance infrared spectra of A) the epoxidized triblock copolymer, B) the silicone resin with 10% (w/w) epoxidized triblock copolymer additive, C) 1% (w/w), 0.1% (w/w), 0.01% (w/w), and 0.001% (w/w) additive, and D) silicone resin without additive. The plot shows that the spectra with the additive are all distinguishable from the base resin. In some embodiments, this may indicate that the additive is surface active.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A polymer composition comprising:
a base polymer; and
a block copolymer additive comprising at least one polysiloxane block and at least one functional block, wherein the functional block comprises at least one branched repeat unit and at least one polarizable organic functionality comprising at least one of: oxygen, nitrogen, sulfur, and a carbon-carbon multiple bond;
wherein the polymer composition has at least one surface, and the surface of the polymer composition has a greater concentration of the block copolymer additive than polymer composition which is not present at the surface; and
wherein the weight ratio of base polymer to block copolymer additive is at least about 9 to 1.

2. The polymer composition of claim 1, wherein the concentration of the block copolymer additive is graded as a function of depth.

3. The polymer composition of claim 1, wherein the polymer composition is prepared by a process comprising:
mixing the block copolymer additive with the base polymer; and
allowing the block copolymer additive to concentrate at the surface.

4. The polymer composition of claim 1, wherein the amount of the block copolymer additive is in the range of about 0.0001% (wt/wt) to about 5% (w/w) of the polymer composition.

5. The polymer composition of claim 1, wherein the amount of the block copolymer additive is in the range of about 0.001% (wt/wt) to about 1% (w/w) of the polymer composition.

6. The polymer composition of claim 1, wherein the amount of the block copolymer additive is in the range of about 0.01% (wt/wt) to about 0.5% (w/w) of the polymer composition.

7. The polymer composition of claim 1, wherein the amount of the block copolymer additive is in the range of about 0.01% (wt/wt) to about 0.1% (w/w) of the polymer composition.

8. The polymer composition of claim 1, wherein the block copolymer additive is substantially free of fluorine.

9. The polymer composition of claim 1, wherein the block copolymer additive is a triblock copolymer of the general formula A-B-A′, wherein A and A′ are independently functional blocks, and B is a polysiloxane block.

10. The polymer composition of claim 1, wherein the polysiloxane block comprises about 5% to about 99% of the mass of the block copolymer additive.

11. The polymer composition of claim 1, wherein the polysiloxane block comprises about 20% to about 95% of the mass of the block copolymer additive.

12. The polymer composition of claim 1, wherein the functional block comprises about 1% to about 95% of the mass of the block copolymer additive.

13. The polymer composition of claim 1, wherein the functional block comprises about 30% to about 50% of the mass of the block copolymer additive.

14. The polymer composition of claim 1, wherein the functional block comprises Si.

15. The polymer composition of claim 1, wherein the polarizable organic functionality is selected from: aldehyde, amine, ammonium, amide, imine, ketimine, imide, azide, azo, carbonate, ketone, carboxamide, carboxyl, carboxylate, epoxide, nitrile, cyanate, isocyanide, isocyanate, isothiocyanate, thioether, disulfide, ester, ether, haloformyl, hydroperoxy, nitro, peroxy, sulfonyl, hydroxyl, sulfhydryl, sulfinyl, thiol, thioether, thioester, sulfonyl, thiocyanate, vinyl, and ethynyl.

16. The polymer composition of claim 1, wherein the functional block comprises an epoxide.

17. The polymer composition of claim 1, wherein the functional block comprises about 2 to about 10,000 repeat units.

18. The polymer composition of claim 1, wherein the functional block comprises:
at least one terminal unit represented by Formula A: 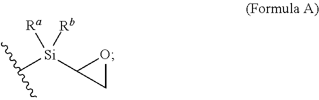
and
at least one repeat unit represented by Formula B: 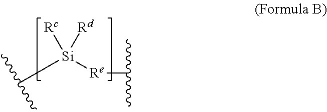
wherein R^{a} and R^{b} are independently C₁₋₆ alkyl, optionally substituted phenyl, or 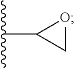
R^{c} and R^{d} are independently C₁₋₆ alkyl, C₂₋₄ alkylene, optionally substituted phenyl, or 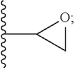
and
R^{e} is C₂₋₄ alkylene.

19. The polymer composition of claim 1, wherein the functional block comprises:
at least one terminal unit represented by Formula 1: 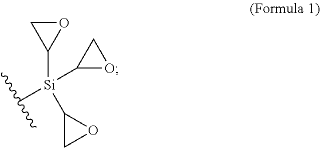
and
at least one repeat unit represented by at least one of Formula 2, Formula 3, and Formula 4: 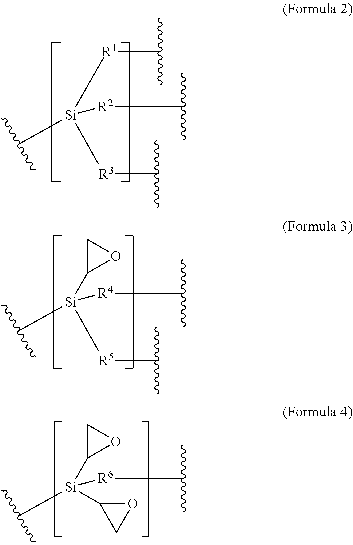
wherein each R¹, R², R³, R⁴, R⁵, and R⁶ is independently —CH₂CH₂— or —CH(CH₃)—.

20. The polymer composition of claim 1, wherein the block copolymer additive comprises at least one repeat unit represented by the formula: 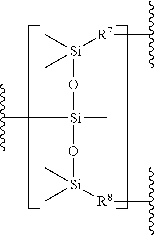
wherein R⁷ and R⁸ are independently —CH₂CH₂— or —CH(CH₃)—.

21. The polymer composition of claim 1, wherein the polysiloxane block comprises polydimethylsiloxane.

22. The polymer composition of claim 1, wherein the polysiloxane block comprises about 1000 to about 200,000 siloxane repeat units.

23. The polymer composition of claim 1, further comprising a second solid polymer which has an amount of covalent bonds to atoms of the functional block that are effective to enhance adhesion to the surface of the base polymer.

24. The polymer composition of claim 23, wherein at least a portion of the covalent bonds to atoms of the functional block comprise —O—, wherein the oxygen atom has one covalent bond to a carbon atom of the functional block and one covalent bond to a carbon atom of the second solid polymer.

25. The polymer composition of claim 23, wherein the second solid polymer is an epoxy resin, a polyurethane, a polyimide, a polysiloxane, or a silicone.

26. A laminated construct comprising:
a first solid polymer comprising silicone and an additive comprising a block copolymer, wherein the block copolymer comprises at least one polysiloxane block and at least one functional block, wherein the functional block comprises at least one branched repeat unit; and
a second solid polymer attached to the first solid polymer at an interface, wherein the attachment between the first solid polymer and the second solid polymer comprises covalent bonding between the functional block of the additive and the second solid polymer at the interface.

27. The laminated construct of claim 26, wherein the block copolymer is substantially free of fluorine.

28. A method of preparing a laminate of at least two different solid polymers, comprising:
providing a first polymer comprising silicone;
mixing a block copolymer additive with the first polymer to form a mixed polymer, wherein the block copolymer additive comprises at least one polysiloxane block and at least one functional block;
concentrating the functional block at a surface of the mixed polymer;
reacting the functional block concentrated at the surface of the mixed polymer with a surface of a second polymer to form an amount of covalent bonds effective to provide enhanced adhesion between the surface of the mixed polymer and the surface of the second polymer;
wherein, if either the mixed polymer or the second polymer is not a solid, each polymer is capable of solidifying after the functional block has concentrated at the surface.

29. The method of claim 28, further comprising
concentrating the functional block at a second surface of the mixed polymer; and
reacting the functional block concentrated at the second surface of the mixed polymer with a surface of a solid material to form an amount of covalent bonds effective to provide enhanced adhesion between the second surface of the mixed polymer and the surface of the solid material.

30. A light-emitting device comprising:
a substrate;
a light-emitting diode; and
the laminated construct of claim 26;
wherein the light-emitting diode is disposed between the substrate and the laminated construct.
